(19) United States
(12) Patent Application Publication
(10) Pub. No.: US 2023/0219982 A1
(43) Pub. Date: Jul. 13, 2023

(54) SILYLATED OLIGOGERMANES AND POLYCYCLIC SILICON-GERMANIUM COMPOUNDS, PROCESSES FOR THEIR PREPARATION AND THEIR USE FOR THE PREPARATION OF A SI- AND GE-CONTAINING SOLID

(71) Applicant: Johann Wolfgang Goethe-Universität, Frankfurt am Main (DE)

(72) Inventors: Matthias WAGNER, Niddatal (DE); Benedikt KÖSTLER, Kelkheim (DE); Hans-Wolfram LERNER, Oberursel (DE)

(21) Appl. No.: 18/000,325

(22) PCT Filed: Jun. 1, 2021
(86) PCT No.: PCT/DE2021/100470

§ 371 Date: Nov. 30, 2022

(30) Foreign Application Priority Data
Jun. 5, 2020 (DE) 10 2020 114 994.8
Nov. 27, 2020 (DE) 10 2020 131 425.6

(51) Int. Cl. C07F 7/30

(52) U.S. Cl. CPC C07F 7/30

(57) ABSTRACT

The present invention relates to a compound of the formula (Ia) or the formula (Ib)

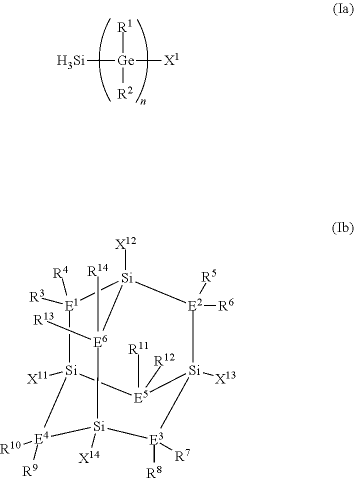

a process for their preparation; and the use of the compound for the preparation of the Si- and Ge-containing solid.

### FIELD OF THE INVENTION

The present invention relates to silylated oligogermanes and polycyclic silicon-germanium compounds, a process for their preparation and their use for the preparation of a Si- and Ge-containing solid.

### BACKGROUND OF THE INVENTION

Halosilanes, polyhalosilanes, halogermanes, polyhalogermanes, silane, polysilanes, germane, polygermanes and corresponding mixed compounds have long been known, cf. WO 2004/036631 A2 or C. J. Ritter et al., J. Am. Chem. Soc., 2005, 127, 9855-9864.

Triphenylgermylsilane and its preparation is described in EP 3 409 645 A1.

Chlorosilylarylgermanes and their preparation are disclosed in EP 3 410 466.

Ritter et al. J. Am. Chem. Soc. 2005, 127, 9855 describes the use of (H₃Ge)ₓSiH₄₋ₓ for the preparation of semiconductor nanostructures on silicon.

Starting from the prior art, it is desirable to prepare improved silicon-germanium compounds, in particular storage-capable silicon-germanium compounds, and to provide a flexible process for the simple preparation of a large number of such compounds. It is also desirable to provide compounds which can be used to produce Si/Ge solids.

The object of the present invention is to overcome disadvantages of the prior art, in particular to prepare storage-capable, tailored silicon-germanium compounds which are suitable for the preparation of Si/Ge solids.

### OVERVIEW OF THE INVENTION

This object is achieved by a compound of the formula (Ia) or (Ib)

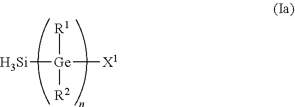

in which formula (Ia)
   n is an integer from 1 to 10;
   R¹ and R² are independently of each other selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl and C₇ to C₂₀ alkylaryl; and
   X¹ is selected from the group consisting of H, SiH₃, halogen and Si(Y¹)₃ with Y¹=halogen;

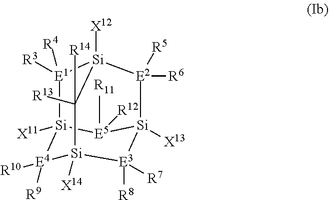

in which formula (Ib)
   E¹ to E⁶ are independently of each other Si or Ge;
   X¹¹ to X¹⁴ are independently of each other selected from the group consisting of H, SiH₃, halogen and Si(Y²)₃;
   Y² is independently selected from C₁ to C₂₀ alkyl and halogen;
   R³ to R¹⁴ are independently of each other selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl, C₇ to C₂₀ alkylaryl and Z; and
   Z is independently selected from the group consisting of H, halogen and C₁ to C₂₀ alkyl.

A Compound of the Formula (Ia)

It may be provided that n is an integer from 1 to 8. It may further be provided that n is an integer from 1 to 6. It may further be provided that n is an integer from 1 to 4. It may also be provided that n is an integer from 2 to 10. It may also be provided that n is an integer from 2 to 8. It may also be provided that n is an integer from 2 to 6. It may also be provided that n is an integer from 2 to 5. Finally, it may be provided that n is an integer from 2 to 4.

It may be provided that R¹ and R² are independently of each other selected from the group consisting of C₁ to C₁₂ alkyl, C₂ to C₁₂ alkenyl, C₂ to C₁₂ alkynyl, C₃ to C₁₂ cycloalkyl, C₆ to C₁₂ aryl, C₇ to C₁₃ arylalkyl and C₇ to C₁₃ alkylaryl.

It may be provided that R¹ and R² are independently of each other selected from the group consisting of C₁ to C₁₂ alkyl, C₆ to C₁₂ aryl, C₇ to C₁₃ arylalkyl and C₇ to C₁₃ alkylaryl.

It may be provided that R¹ and R² are independently of each other selected from the group consisting of C₁ to C₂₀ alkyl and C₆ to C₂₀ aryl.

It may be provided that R¹ and R² are independently of each other selected from the group consisting of C₁ to C₁₂ alkyl and C₆ to C₁₂ aryl.

It may be provided that R¹ and R² are independently of each other phenyl or methyl.

It may be provided that R¹ and R² are the same. In this context, it may be provided that all R¹ and R² contained in the compound of the formula (Ia) are the same and are selected from one of the groups mentioned above.

It may be provided that X¹ is selected from the group consisting of H, SiH₃, Cl and SiCl₃.

A Compound of the Formula (Ib)

It may be provided that at least three of E¹ to E⁶ are Ge and the remaining of E¹ to E⁶ are Si. It may be provided that four, five or six of E¹ to E⁶ are Ge and the remaining of E¹ to E⁶ are Si. It may be provided that four or five of E¹ to E⁶ are Ge and the remaining of E¹ to E⁶ are Si.

It may be provided that R³ to R¹⁴ are independently of each other selected from the group consisting of C₁ to C₁₂ alkyl, C₂ to C₁₂ alkenyl, C₂ to C₁₂ alkynyl, C₃ to C₁₂ cycloalkyl, C₆ to C₁₂ aryl, C₇ to C₁₃ arylalkyl, C₇ to C₁₃ alkylaryl and halogen.

It may be provided that R³ to R¹⁴ are independently of each other selected from the group consisting of C₁ to C₁₂ alkyl, C₆ to C₁₂ aryl, C₇ to C₁₃ arylalkyl, C₇ to C₁₃ alkylaryl and halogen.

It may be provided that R³ to R¹⁴ are independently of each other selected from the group consisting of C₁ to C₂₀ alkyl, C₆ to C₂₀ aryl and halogen.

It may be provided that R³ to R¹⁴ are independently of each other selected from the group consisting of C₁ to C₁₂ alkyl and halogen.

It may be provided that R³ to R¹⁴ are independently of each other Cl or methyl.

It may be provided that two Rⁿ directly connected to the same E^{m} (i.e., the two R in the pairs R³ and R⁴, R⁵ and R⁶, R⁷ and R⁸, R⁹ and R¹⁰, R¹¹ and R¹², and R¹³ and R¹⁴) are the same.

It may be provided that in the case that the E^{m} (i.e., one of E¹ to E⁶) is Ge, the two Rⁿ directly connected to the E^{m} are C₁ to C₂₀ alkyl. It may be provided that in the case that the E^{m} (i.e., one of E¹ to E⁶) is Ge, the two Rⁿ directly connected to the E^{m} are C₁ to C₁₂ alkyl. It may be provided that in the case that the E^{m} (i.e., one of E¹ to E⁶) is Ge, the two Rⁿ directly connected to the E^{m} are C₁ to C₈ alkyl. It may be provided that in the case that the E^{m} (i.e., one of E¹ to E⁶) is Ge, the two Rⁿ directly connected to the E^{m} are C₁ to C₄ alkyl. It may be provided that in the case that the E^{m} (i.e., one of E¹ to E⁶) is Ge, the two Rⁿ directly connected to the E^{m} are methyl.

It may be provided that in the case that the E^{m} (i.e., one of E¹ to E⁶) is Si, the two Rⁿ directly connected to the E^{m} are halogen. It may be provided that in the case that the E^{m} (i.e., one of E¹ to E⁶) is Si, the two Rⁿ directly connected to the E^{m} are Cl.

It may be provided that X¹¹ to X¹⁴ are independently selected from the group consisting of H, SiH₃, Si(C₁ to C₂₀ alkyl)₃, Cl and SiCl₃. It may be provided that X¹¹ to X¹⁴ are independently of each other selected from the group consisting of H, SiH₃, Si(C₁ to C₁₂ alkyl)₃, Cl and SiCl₃. It may be provided that X¹¹ to X¹⁴ are independently of each other selected from the group consisting of H, SiH₃, Si(C₁ to C₈ alkyl)₃, Cl and SiCl₃. It may be provided that X¹¹ to X¹⁴ are independently of each other selected from the group consisting of H, SiH₃, Si(C₁ to C₄ alkyl)₃, Cl and SiCl₃. It may be provided that X¹¹ to X¹⁴ are independently of each other selected from the group consisting of Si(C₁ to C₄ alkyl)₃ and SiCl₃.

It may be provided that the compound of the formula (Ib) is selected from one of the following compounds C1 to C4.

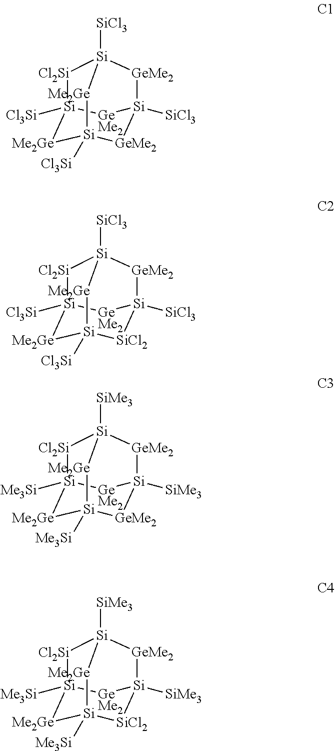

Process for Preparing a Compound of the Formula (Ia)

The object is further achieved by a process for preparing a compound of the formula (Ia) according to one of the preceding claims comprising reacting a compound of the formula (IIa)

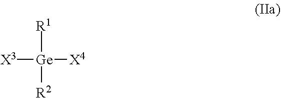

with a compound of the formula (IIIa)

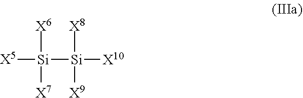

wherein X³ to X¹⁰ are independently halogen; and R¹ and R² are as defined above; and hydrogenating the product obtained by reacting the compound of the formula (IIa) with the compound of the formula (IIIa).

The ratio of compound (IIa) to compound (IIIa) can be from 10:1 to 1:20; 5:1 to 1:1; 2:1 to 1:10; 1.5:1 to 1:8; 1.2:1 to 1:5; 1:1 to 1:4.

It can be provided that the reaction of the compound of the formula (IIa) with the compound of the formula (IIIa) is carried out in the presence of a catalyst. It can be provided to use the catalyst in amounts of from 0.001 to 1 eq., preferably from 0.01 to 0.1 eq. It can be provided that the catalyst is a base. It can be provided that the catalyst is a base containing phosphorus or nitrogen. It can be provided that the catalyst is a base containing nitrogen. It can be provided that the catalyst is a phosphonium or ammonium salt. It can be provided that the catalyst is selected from [(R′)₄P]Cl or [(R′)₄N]Cl, wherein the radicals R′ are independently of each other selected from C₁ to C₁₂ alkyl, C₆ to C₁₂ aryl, C₇ to C₁₃ arylalkyl and C₇ to C₁₃ alkylaryl. It can be provided that the catalyst is [(R′)₄N]Cl, wherein R′ is selected from methyl, ethyl, isopropyl, n-butyl and phenyl. It can be provided that the catalyst is [(R′)₄N]Cl, wherein R′ is selected n-butyl.

It can be provided that the reaction of the compound of the formula (IIa) with the compound of the formula (IIIa) is carried out in a solvent. In the process, at least 5 mol of solvent can be used per mol of compound (IIIa), alternatively from 10 mol to 100 mol of solvent per mol of compound (IIIa). It can be provided that the solvent is an organic solvent. It can be provided that the solvent (both in the reaction step and in the hydrogenation step) is a non-polar organic solvent. It can be provided that the solvent is selected from n-pentane, n-hexane, n-heptane, cyclohexane, toluene, diethyl ether, dichloromethane, chloroform, tert-butyl methyl ether, acetone and tetrahydrofuran. It can be provided that the solvent is dichloromethane.

It can be provided that the reaction of the compound of the formula (IIa) with the compound of the formula (IIIa) is carried out at a temperature in a range from 0° C. to 50° C., 10° C. to 40° C., 15° C. to 30° C., 20° C. to 25° C., or 22° C. (=room temperature).

It can be provided that the reaction of the compound of the formula (IIa) with the compound of the formula (IIIa) is carried out for 5 min to 24 h, 30 min to 12 h, or 1 h to 4 h.

It can be provided that the hydrogenation of the product obtained by reacting the compound of the formula (IIa) with the compound of the formula (IIIa) is carried out by adding a hydrogenating agent. It can be provided that the hydrogenating agent is lithium aluminum hydride.

Process for Preparing a Compound of the Formula (Ib)

The object is further achieved by a process for preparing a compound of the formula (Ib) according to one of the preceding claims comprising reacting a compound of the formula (IIb)

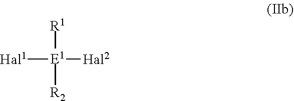

with a compound of the formula (IIIb)

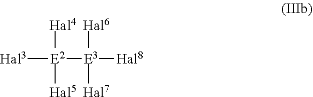

wherein Hal¹ to Hal⁸ are independently halogen; and R³ and R⁴ are as defined above; and
crystallizing the product of the reaction of the compounds (IIb) and (IIIb).

It may be provided that in the process E¹=Ge and E² and E³ are each Si.

The molar ratio of compound (IIb) to compound (IIIb) can be from 10:1 to 1:40; 5:1 to 1:2; 2:1 to 1:20; 1.5:1 to 1:10; 1.2:1 to 1:8; 1:3 to 1:5, about 1:4.

It can be provided that the reaction of the compound of the formula (IIb) with the compound of the formula (IIIb) is carried out in the presence of a catalyst. It can be provided to use the catalyst in amounts of from 0.001 to 1 eq., preferably from 0.01 to 0.1 eq. It can be provided that the catalyst is a base. It can be provided that the catalyst is a base containing phosphorus or nitrogen. It can be provided that the catalyst is a base containing nitrogen. It can be provided that the catalyst is a phosphonium or ammonium salt. It can be provided that the catalyst is selected from [(R³)₄P]Cl or [(R³)₄N]Cl, wherein the radicals R³ are independently of each other selected from C₁ to C₁₂ alkyl, C₆ to C₁₂ aryl, C₇ to C₁₃ arylalkyl and C₇ to C₁₃alkylaryl. It can be provided that the catalyst is [(R³)₄N]Cl, wherein R³ is selected from methyl, ethyl, isopropyl, n-butyl and phenyl. It can be provided that the catalyst is [(R³)₄N]Cl, wherein R³ is selected n-butyl.

It can be provided that the reaction of the compound of the formula (IIb) with the compound of the formula (IIIb) is carried out in a solvent. In the process, at least 5 mol of solvent can be used per mol of compound (IIIb), alternatively from 10 mol to 100 mol of solvent per mol of compound (IIIb). It can be provided that the solvent is an organic solvent. It can be provided that the solvent (both in the reaction step and in the hydrogenation step) is a non-polar organic solvent. It can be provided that the solvent is selected from n-pentane, n-hexane, n-heptane, cyclohexane, toluene, diethyl ether, dichloromethane, chloroform, tert-butyl methyl ether, acetone and tetrahydrofuran. It can be provided that the solvent is dichloromethane.

It can be provided that the reaction of the compound of the formula (IIb) with the compound of the formula (IIIb) is carried out at a temperature in a range from 0° C. to 50° C., 10° C. to 40° C., 15° C. to 30° C., 20° C. to 25° C., or 22° C. (=room temperature).

It can be provided that the reaction of the compound of the formula (IIb) with the compound of the formula (IIIb) is carried out for 5 min to 24 h, 30 min to 12 h, or 1 h to 4 h.

It can be provided that the process further comprises reacting the product obtained after the crystallization with a Grignard reagent. A Grignard reagent is a compound of the general formula R—Mg-Hal with R=acyl (for example aryl or alkyl) and Hal=halogen (for example Cl or Br). Such a compound can be prepared by reacting acyl halide with magnesium in a suitable organic solvent. Suitable organic solvents are those which can form a coordinate bond to the Mg in the R—Mg-Hal by a free electron pair. An ether (preferably a dialkyl ether such as diethyl ether or a cyclic ether such as tetrahydrofuran (THF)) is preferably used as organic solvent. Grignard reagents and their preparation and use are well known from the prior art, in particular relevant textbooks of organic chemistry.

It can be provided that a compound of the formula (Ib) with X¹¹ to X¹⁴═Si(acyl)₃ is obtained by reacting a compound of the formula (Ib) with X¹¹ to X¹⁴=SiHal₃ with a Grignard reagent of the formula R—Mg-Hal with R=acyl in THF or diethyl ether. It can be provided that a compound of the formula (Ib) with X¹¹ to X¹⁴═Si(alkyl)₃ is obtained by reacting a compound of the formula (Ib) with X¹¹ to X¹⁴=SiHal₃ with a Grignard reagent of the formula R—Mg-Hal with R=alkyl in THF or diethyl ether. It can be provided that a compound of the formula (Ib) with X¹¹ to X¹⁴═Si(C₁ to C₄ alkyl)₃ is obtained by reacting a compound of the formula (Ib) with X¹¹ to X¹⁴=SiHal₃ with a Grignard reagent of the formula R—Mg-Hal with R═C₁ to C₄ alkyl in diethyl ether. It can be provided that a compound of the formula (Ib) with X¹¹ to X¹⁴ ═SiMe₃ is obtained by reacting a compound of the formula (Ib) with X¹¹ to X¹⁴═SiCl₃ with a Grignard reagent of the formula R—Mg-Hal with R=methyl in diethyl ether.

Preparation of a Si- and Ge-Containing Solid

The object is also achieved by the use of a compound according to the formula (Ia) or the formula (Ib) described above for preparing a Si- and Ge-containing solid.

It may be provided that the Si- and Ge-containing solid is an intermetallic phase, wherein the two semimetals Si and Ge are to be regarded as metals in this context. An intermetallic phase (also intermetallic compound) is a chemical compound of two or more metals. In contrast to alloys, the intermetallic phase has lattice structures which differ from those of the constituent metals. The lattice bond of the different atom types is a mixed form of a predominantly metallic bond and smaller proportions of other types of bonds (covalent bond, ion bond), whereby these phases have particular physical and mechanical properties.

It may be provided that the preparation of the Si- and Ge-containing solid comprises heating the compound to a temperature of 300° C. or more. It may be provided that the preparation of the Si- and Ge-containing solid comprises heating the compound to a temperature of 400° C. or more. It may be provided that the preparation of the Si- and Ge-containing solid comprises heating the compound to a temperature of 450° C. or more. It may be provided that the preparation of the Si- and Ge-containing solid comprises heating the compound to a temperature of 500° C. or more. It may be provided that the preparation of the Si- and Ge-containing solid comprises heating the compound to a temperature of 550° C. or more. It may be provided that the preparation of the Si- and Ge-containing solid comprises heating the compound to a temperature of 600° C. or more. It may be provided that the preparation of the Si- and Ge-containing solid comprises heating the compound to a temperature of 400° C. to 1000° C. It may be provided that the preparation of the Si- and Ge-containing solid comprises heating the compound to a temperature of 400° C. to 800° C. It may be provided that the preparation of the Si- and Ge-containing solid comprises heating the compound to a temperature of 450° C. to 750° C. It may be provided that the preparation of the Si- and Ge-containing solid comprises heating the compound to a temperature of 500° C. to 700° C. It may be provided that the preparation of the Si- and Ge-containing solid comprises heating the compound to a temperature of 550° C. to 650° C. It may be provided that the preparation of the Si- and Ge-containing solid comprises heating the compound to a temperature of about 600° C.

It may be provided that the preparation of the Si- and Ge-containing solid comprises depositing SiGe. It may be provided that the preparation of the Si- and Ge-containing solid comprises simultaneously depositing Si and Ge. It may be provided that the stoichiometric ratio of Si to Ge in the Si- and Ge-containing solid corresponds to the stoichiometric ratio of Si to Ge in the compound of the formula (Ia) or the formula (Ib). It may be provided that the stoichiometric ratio of Si to Ge in the Si- and Ge-containing solid corresponds to the stoichiometric ratio of Si to Ge in the compound of the formula (Ia) or the formula (Ib) with a deviation of 10%.

It may be provided that the Si- and Ge-containing solid contains further elements in an amount of 10% by weight or less, based on the total weight of the Si- and Ge-containing solid. It may be provided that the Si- and Ge-containing solid contains further elements in an amount of 5% by weight or less, based on the total weight of the Si- and Ge-containing solid. It may be provided that the Si- and Ge-containing solid contains further elements in an amount of 3% by weight or less, based on the total weight of the Si- and Ge-containing solid. It may be provided that the Si- and Ge-containing solid contains further elements in an amount of 2% by weight or less, based on the total weight of the Si- and Ge-containing solid. It may be provided that the Si- and Ge-containing solid contains further elements in an amount of 1% by weight or less, based on the total weight of the Si- and Ge-containing solid. It may be provided that the Si- and Ge-containing solid contains further elements in an amount of 0.5% by weight or less, based on the total weight of the Si- and Ge-containing solid. It may be provided that the Si- and Ge-containing solid contains further elements in an amount of 0.1% by weight or less, based on the total weight of the Si- and Ge-containing solid. It may be provided that the Si- and Ge-containing solid contains further elements in an amount of 0.01% by weight or less, based on the total weight of the Si- and Ge-containing solid. It may be provided that the Si- and Ge-containing solid contains further elements in an amount of 0.001% by weight or less, based on the total weight of the Si- and Ge-containing solid.

It may be provided that further elements contained in the Si- and Ge-containing solid are selected from the group consisting of carbon, oxygen, aluminum and mixtures thereof.

It may be provided that the heating of the compound of the formula (Ia) or of the formula (Ib)

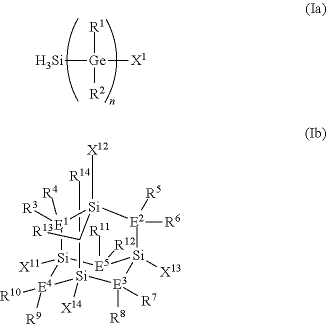

during the preparation of the Si- and Ge-containing solid is accompanied by the formation of R¹—H and R²—H, or R³—H and R⁴—H.

The term “alkyl” as used herein refers to mono-radical of a saturated chain or branched hydrocarbon. Preferably, the alkyl group comprises 1 to 12 (about 1 to 10) carbon atoms, i.e. 1, 2, 3, 4, 5, 6, 7, 8, 9, 10, 11 or 12 carbon atoms, preferably 1 to 8 carbon atoms, alternatively 1 to 6 or 1 to 4 carbon atoms. Exemplary alkyl groups are methyl, ethyl, propyl, isopropyl, butyl, isobutyl, tert-butyl, n-pentyl, isopentyl, sec-pentyl, neopentyl, 1,2-dimethylpropyl, iso-amyl, n-hexyl, iso-hexyl, sec-hexyl, n-heptyl, iso-heptyl, n-octyl, 2-ethylhexyl, n-nonyl, n-decyl, n-undecyl or n-dodecyl.

The term “alkenyl” as used herein refers to the mono-radical of a saturated chain or branched hydrocarbon having at least one double bond.

The term “alkynyl” as used herein refers to the mono-radical of a saturated chain or branched hydrocarbon having at least one triple bond.

The term “aryl” as used herein refers to the mono-radical of an aromatic cyclic hydrocarbon. Preferably, the aryl group contains 5 to 14 (e.g. 5, 6, 7, 8, 9, 10) carbon atoms, which may be arranged in one ring (e.g. “phenyl”=“Ph”) or in two or more fused rings (e.g. “naphthyl”). Exemplary aryl groups are, for example, cyclopentadienyl, phenyl, indenyl, naphthyl, azulenyl, fluorenyl, anthryl, and phenanthryl.

The term “cycloalkyl” as used herein refers to the cyclic, non-aromatic form of an alkyl.

The term “arylalkyl” as used herein refers to an aryl group substituted with at least one alkyl, e.g. tolueneyl.

The term “alkylaryl” as used herein refers to an alkyl group substituted with at least one aryl, e.g. 2-phenylethyl.

The term “halogen” as used herein refers to fluorine, chlorine, bromine, or iodine.

### DETAILED DESCRIPTION OF THE INVENTION

The invention will be described in detail below with reference to particularly preferred embodiments and exemplary embodiments. However, the invention is not limited to these particularly preferred embodiments and exemplary embodiments, wherein individual features of the particularly preferred embodiments and exemplary embodiments together with other features or features of the preceding general disclosure of the invention can serve to realize the invention.

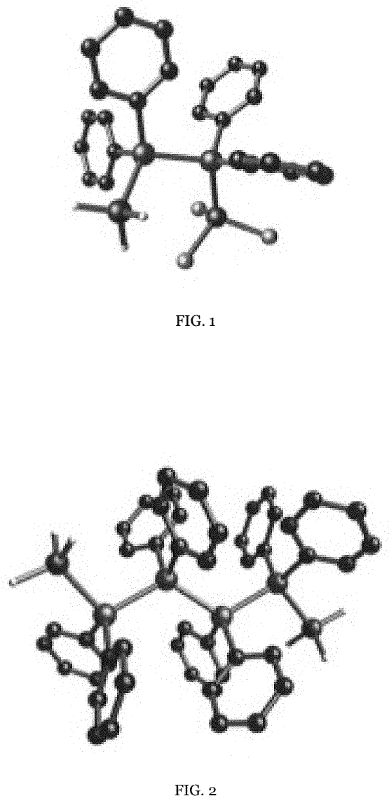

FIG. 1 shows the crystal structure of the compound A7.

FIG. 2 shows the crystal structure of the compound A8.

The present invention relates to the novel silylated oligogermanes of the formula (Ia)

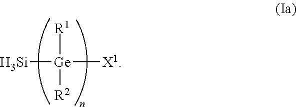

The present invention also relates to the novel polycyclic silicon-germanium compounds of the formula (Ib)

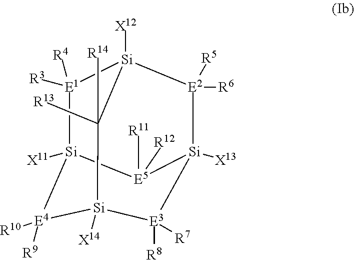

Compounds of the formula (Ia) are obtainable via a novel synthesis, for example starting from diorganyldichlorogermane and hexachlorodisilane. The target compounds (Ia) can be prepared, for example, by adding tetrabutylammonium chloride and subsequent hydration with lithium aluminum hydride. These oligogermanes are distinguished by their thermolysis behavior, for example, in the deposition of pure Si and Ge, the residue obtained here consisting of pure Si and Ge in the stoichiometric ratio.

Compounds of the formula (Ib) are obtainable via a novel synthesis, for example starting from diorganyldichlorogermane and hexachlorodisilane. The target compounds (Ib) can be prepared, for example, by adding tetrabutylammonium chloride and optionally subsequent reaction with a Grignard reagent. These polycyclic silicon-germanium compounds are distinguished by their thermolysis behavior, for example, in the deposition of pure Si and Ge, the residue obtained here consisting of pure Si and Ge in the stoichiometric ratio.

General Synthesis Route for the Compounds of the Formula (Ia)

The reaction of diorganodichlorogermanes with hexachlorodisilane with addition of tetrabutylammonium chloride followed by hydrogenation with LialH4 leads to the selective formation of the silylated oligogermanes H₃Si—(GeR₂)ₙ—X¹ (where n=1-4; R=alkyl, aryl; X¹═H, Cl, SiH₃, SiCl₃).

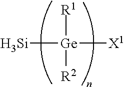

Particularly preferred compounds which can be prepared in this way are the following compounds A1 to A8

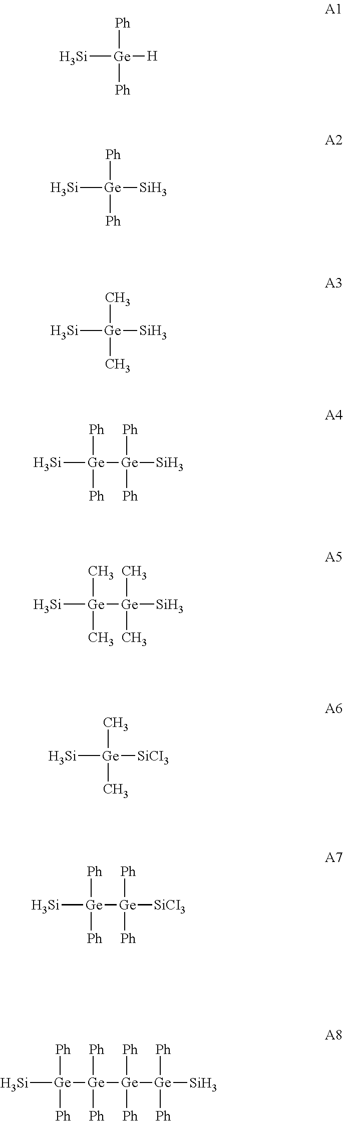

The compounds according to the invention can be prepared according to the following Scheme 1.

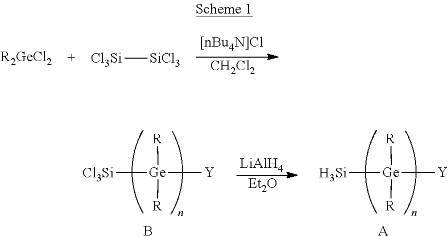

Scheme 1 shows the reaction of diorganodichlorogermanes with hexachlorodisilane with addition of tetrabutylammonium chloride to give the trichlorosilylated oligogermanes Cl3Si—(GeR₂)ₙ—Y (B, where n=1-4; R=alkyl, aryl; Y═Cl, SiCl₃). The subsequent hydrogenation with LiAlH4 leads to the selective formation of the silylated oligogermanes H₃Si—(GeR₂)ₙ—Y (A, m it n=1-4; R=alkyl, aryl; Y═H, Cl, SiH₃, SiCl₃).

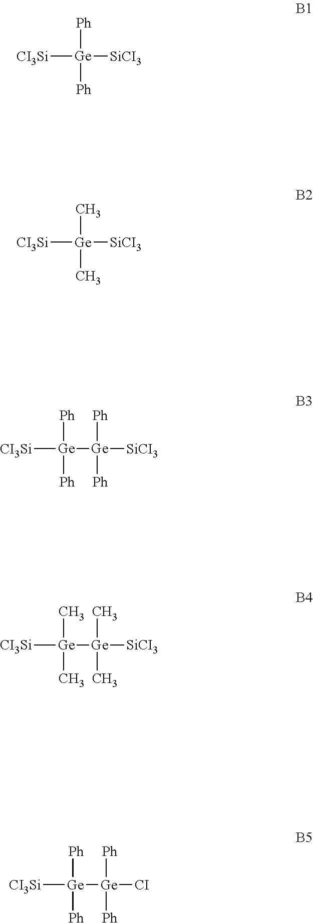

Synthesis Examples for the Compounds of the Formula (Ia)

Synthesis of Cl₃Si-Ph₂Ge—SiCl₃ (B1)

A solution of [nBu₄N]Cl (90 mg, 0.34 mmol, 0.2 eq.), Ph₂GeCl₂ (500 mg, 1.70 mmol, 1 eq.), 5 ml of CH₂Cl₂ and Si₂Cl₆ (1800 mg, 6.80 mmol, 4 eq.) was stirred at room temperature overnight and then freed from all volatile constituents under reduced pressure. The orange-colored viscous residue was extracted with 6 ml of n-hexane and all volatile constituents were removed from the filtrate under reduced pressure. In this way, Cl₃Si-Ph₂Ge—SiCl₃ (79%, 659 mg, 1.34 mmol) was obtained as a colorless, viscous liquid.

¹H NMR (500.2 MHz, CD₂Cl₂, 298 K): δ=7.57-7.52 (m, 4H), 7.44-7.35 ppm (m, 6H).

¹³C{¹H} NMR (125.8 MHz, CD₂Cl₂, 298 K): δ=136.0 (ortho), 131.1 (para), 129.9 (meta), 129.4 ppm (ipso).

²⁹Si NMR (99.4 MHz, CD₂Cl₂, 298 K): δ=9.7 ppm.

EA (%): Calculated for C₁₂H₁₀Si₂Cl₆Ge [495.70 g/mol]: C 29.08, H 2.03; found: C 29.51, H 2.07.

Synthesis of Cl₃Si-Me₂Ge—SiCl₃ (B2)

[nBu₄N]Cl (200 mg, 0.73 mmol, 0.2 eq.), Me₂GeCl₂ (500 mg, 3.63 mmol, 1 eq.), 10 ml of CH₂Cl₂ and Si₂Cl₆ (1950 mg, 7.26 mmol, 2 eq.) were stirred at room temperature for 3 hours and then all volatile constituents were removed under reduced pressure. The crude product was extracted twice with 5 ml of n-hexane each time and all volatile constituents were removed from the filtrate under reduced pressure. In this way, 370 mg of a colorless liquid were obtained. NMR spectroscopy and GC/MS confirmed the presence of a mixture of Cl₃Si-Me₂Ge—SiCl₃ and Cl₃Si-Me₂Ge-Me₂Ge—SiCl₃.

Cl₃Si-Me₂Ge—SiCl₃ was identified using the following signals:

¹H NMR (500.2 MHz, CD₂Cl₂, 298 K): δ=0.79 ppm (s, 6H).

¹³C{¹H} NMR (125.8 MHz, CD₂Cl₂, 298 K): δ=−5.2 ppm.

²⁹Si NMR (99.4 MHz, CD₂Cl₂, 298 K): δ=13.2 ppm.

Synthesis of Cl₃Si-Ph₂Ge-Ph₂Ge—SiCl₃ (B3)

[nBu₄N]Cl (180 mg, 0.65 mmol, 0.2 eq.), Ph₂GeCl₂ (900 mg, 3.02 mmol, 1 eq.), 10 ml of CH₂Cl₂ and Si₂Cl₆ (1600 mg, 5.95 mmol, 2 eq.) were stirred at room temperature for 3 hours and then all volatile constituents were removed under reduced pressure. The crude product was washed dropwise with a total of 2.5 ml of CH₂Cl₂ in order to obtain Cl₃Si-Ph₂Ge-Ph₂Ge—SiCl₃ as a colorless solid in 88% yield (956 mg, 1.32 mmol).

¹H NMR (500.2 MHz, CD₂Cl₂, 298 K): δ=7.62-7.56 (m, 8H), 7.54-7.38 ppm (m, 12H).

¹³C{¹H} NMR (125.8 MHz, CD₂Cl₂, 298 K): δ=136.3 (ortho), 132.2 (ipso), 130.5 (para), 129.4 ppm (meta).

²⁹Si NMR (99.4 MHz, CD₂Cl₂, 298 K): δ=12.4 ppm.

EA (%): Calculated for C₂₄H₂₀Si₂Cl₆Ge₂ [722.55 g/mol]: C 39.90, H 2.79; found: C 40.64, H 3.02.

Synthesis of Cl₃Si-Me₂Ge-Me₂Ge—SiCl₃ (B4)

[nBu4N]Cl (800 mg, 2.91 mmol, 0.4 eq.), Me₂GeCl₂ (1000 mg, 7.27 mmol, 1 eq.), 20 ml of CH₂Cl₂ and Si₂Cl₆ (3900 mg, 14.54 mmol, 2 eq.) were stirred at room temperature for 24 hours and then all volatile constituents were removed under reduced pressure. The crude product was extracted four times with 5 ml of n-hexane each time and all volatile constituents were removed from the filtrate under reduced pressure. In this way, Cl₃Si-Me₂Ge-Me₂Ge—SiCl₃ (34%, 589 mg, 1.24 mmol) was obtained as a colorless liquid.

¹H NMR (500.2 MHz, CD₂Cl₂, 298 K): δ=0.72 ppm (s, 12H).

¹³C{¹H} NMR (125.8 MHz, CD₂Cl₂, 298 K): δ=−4.3 ppm.

²⁹Si NMR (99.4 MHz, CD₂Cl₂, 298 K): δ=16.7 ppm.

Synthesis of Cl₃Si-Ph₂Ge-Ph₂Ge—Cl (B5)

[nBu₄N]Cl (10 mg, 0.03 mmol, 0.1 eq.), Ph₂GeCl₂ (100 mg, 0.34 mmol, 1 eq.), 1 ml of CD₂Cl₂ and Si₂Cl₆ (90 mg, 0.34 mmol, 1 eq.) were mixed in a glass and then half the batch was added to an NMR tube. After melting in oil pump vacuum, Cl-Ph₂Ge-Ph₂Ge—Cl, Cl₃Si-Ph₂Ge-Ph₂Ge—SiCl and Cl₃Si-Ph₂Ge-Ph₂Ge—SiCl₃ were detected in the reaction solution by means of NMR spectroscopy.

Cl₃Si-Ph₂Ge-Ph₂Ge—Cl was identified using the following signals:

¹H NMR (500.2 MHz, CD₂Cl₂, 298 K): δ=7.80-7.00 (m, 20H).

¹³C{¹H} NMR (125.8 MHz, CD₂Cl₂, 298 K): Cl₃Si-Ph₂Ge-Ph₂Ge—Cl: δ=136.6 (ipso), 136.1 (ortho), 134.1 (ortho), 131.8 (ipso), 131.0 (para), 130.6 (para), 129.5 (meta), 129.2 ppm (meta).

²⁹Si NMR (99.4 MHz, CD₂Cl₂, 298 K): δ=12.1 ppm.

Synthesis of H₃Si-Ph₂Ge—H (A1)

The product from the synthesis of H₃Si-Ph₂Ge—SiH₃ was stored at room temperature for 6 months. The subsequent investigation by means of NMR spectroscopy and GC/MS confirmed the formation of H₃Si-Ph₂Ge—H.

H₃Si-Ph₂Ge—H was identified using the following signals:

¹H NMR (500.2 MHz, CD₂Cl₂, 298 K): δ=7.70-7.20 (m), 5.07 (Ge—H, q, J=3.2 Hz, 1H), 3.57 ppm (SiH3, d, J=3.2 Hz, 3H).

¹³C{¹H} NMR (125.8 MHz, CD₂Cl₂, 298 K): δ=136.1 (ipso), 135.5 (ortho), 129.3 (para), 128.9 ppm (meta).

²⁹Si NMR (99.4 MHz, CD₂Cl₂, 298 K): δ=−94.9 ppm (qd, ¹J_{HSI}=199.7 Hz, ²J_{HSI}=13.3 Hz).

Synthesis of H₃Si-Ph₂Ge—SiH₃ (A2)

Cl₃Si-Ph₂Ge—SiCl₃ (400 mg, 0.807 mmol, 1 eq.) was dissolved in 10 ml of Et₂O and LiAlH₄ (93 mg, 2.42 mmol, 3 eq.) was added in portions. The solution remained clear and colorless and a gray solid precipitated. After stirring for 30 minutes, all volatile constituents were removed under reduced pressure and the residue was stirred with 8 ml of n-hexane for 16 hours. Filtration of the n-hexane solution and liberation of the extract from all volatile constituents under reduced pressure yielded H₃Si-Ph₂Ge—SiH₃ (55%, 128 mg, 0.443 mmol) as a viscous, colorless liquid. The product was identified by means of NMR spectroscopy and GC/MS.

¹H NMR (500.2 MHz, CD₂Cl₂, 298 K): δ=7.42-7.38 (m, 4H), 7.27-7.23 (m, 6H), 3.50 ppm (s, 6H).

¹³C{¹H} NMR (125.8 MHz, CD₂Cl₂, 298 K): δ=136.8 (ipso), 135.4 (ortho), 129.1 (para), 128.9 ppm (meta).

²⁹Si NMR (99.4 MHz, CD₂Cl₂, 298 K): δ=−91.2 ppm (qq, ¹J_{HSI}=200 Hz, ³J_{HSI}=3 Hz).

Synthesis of H₃Si-Me₂Ge—SiH₃ (A3) and H₃Si-Me₂Ge-Me₂Ge—SiH₃ (A5)

50 mg of a mixture of Cl₃Si-Me₂Ge—SiCl₃ (B2) and Cl₃Si-Me₂Ge-Me₂Ge—SiCl₃ (B4) was dissolved in 0.8 ml of Et₂O in an NMR tube and an excess of LiAlH₄ (15 mg, 0.4 mmol, about 3 eq.) was slowly added. 0.2 ml of the solution was taken for a GC/MS sample and diluted with a further 0.5 ml of Et₂O. The remaining reaction solution was melted in the NMR tube under vacuum and measured by NMR spectroscopy. GC/MS and NMR spectroscopy confirmed the formation of H₃Si-Me₂Ge—SiH₃ and H₃Si-Me₂Ge-Me₂Ge—SiH₃.

¹H NMR (500.2 MHz, Et₂O, 298 K): δ=0.93 ppm; H₃Si-Me₂Ge-Me₂Ge-SiH₃: δ=0.89 ppm.

¹³C{¹H} NMR (125.8 MHz, Et₂O, 298 K): δ=−4.0 ppm; H₃Si-Me₂Ge-Me₂Ge-SiH₃: δ=−4.8 ppm.

²⁹Si NMR (99.4 MHz, Et₂O, 298 K): δ=−90.8 ppm (qm, ¹J_{HSI}=196 Hz); H₃Si-Me₂Ge-Me₂Ge-SiH₃: δ=−94.7 ppm (qm, ¹J_{HSI}=191 Hz).

Synthesis of H₃Si-Ph₂Ge-Ph₂Ge—SiH₃ (A4)

Cl₃Si-Ph₂Ge-Ph₂Ge—SiCl₃ (200 mg, 0.280 mmol, 1 eq.) was dissolved in 6 ml of Et₂O and LiAlH₄ (37 mg, 0.98 mmol, 3.5 eq.) was added in portions. The solution remained clear and colorless and a gray solid precipitated. After stirring for 30 minutes, all volatile constituents were removed under reduced pressure and the residue was stirred with 8 ml of n-hexane for 16 hours. Filtration of the n-hexane solution and liberation of the extract from all volatile constituents under reduced pressure yielded H₃Si-Ph₂Ge-Ph₂Ge—SiH₃ (55%, 128 mg, 0.44 mmol) as a colorless, crystalline solid. The product was identified by means of NMR spectroscopy.

¹H NMR (500.2 MHz, CD₂Cl₂, 298 K): δ=7.44-7.39 (m, 8H), 7.38-7.27 (m, 13H), 3.60 ppm (s, 6H).

¹³C{¹H} NMR (125.8 MHz, CD₂Cl₂, 298 K): δ=127.1 (ipso), 135.8 (ortho), 129.1 (para), 128.8 ppm (meta).

²⁹Si NMR (99.4 MHz, CD₂Cl₂, 298 K): δ=−92.6 ppm (q, ¹J_{HSI}=199.6 Hz).

Synthesis of H₃Si-Ph₂Ge—SiCl₃ (A6)

Cl₃Si-Ph₂Ge—SiCl₃ (50 mg, 0.10 mmol, 1 eq.) in 0.5 ml of Et₂O was initially charged in an NMR tube and LiAlH₄ (6 mg, 0.14 mmol, 1.4 eq.) was added. A gray solid precipitated from the colorless reaction solution. ¹³C and ²⁹Si NMR spectroscopy showed Cl₃Si-Ph₂Ge—SiCl₃, H₃Si-Ph₂Ge—SiCl₃ and H₃Si-Ph₂Ge—SiH₃ as reaction products.

NMR signals of H₃Si-Ph₂Ge—SiCl₃:

¹³C{¹H} NMR (125.8 MHz, Et₂O, 298 K): δ=135.7 (ortho), 132.6 (ipso), 130.4 (para), 129.7 ppm (meta).

²⁹Si NMR (99.4 MHz, Et₂O, 298 K): δ=15.7, −93.4 ppm (q, ¹J_{HSI}=207 Hz).

Synthesis of H₃Si-Ph₂Ge-Ph₂Ge—SiCl₃ (A7)

Cl₃Si-Ph₂Ge-Ph₂Ge—SiCl₃ (200 mg, 0.280 mmol, 1 eq.) in 2 ml of Et₂O was initially charged and LiAlH₄ (10 mg, 0.28 mmol, 1 eq.) was slowly added. The solution remained colorless and a gray solid precipitated. The solid was filtered off and the filtrate was freed from the solvent under ambient pressure. The residue was extracted with 4 ml of n-hexane and then all volatile constituents of the extract were removed under ambient pressure. ¹³C and ²⁹Si NMR spectroscopy of the solid obtained confirmed the presence of the starting material Cl₃Si-Ph₂Ge-Ph₂Ge—SiCl₃, H₃Si-Ph₂Ge-Ph₂Ge—SiCl₃ and H₃Si-Ph₂Ge-Ph₂Ge—SiH₃. It was also possible to obtain the crystal structure of H₃Si-Ph₂Ge-Ph₂Ge—SiCl₃ by means of X-ray diffractometry.

NMR signals of H₃Si-Ph₂Ge-Ph₂Ge—SiCl₃:

¹³C{1H} NMR (125.8 MHz, CD₂Cl₂, 298 K): δ=136.2 (ortho), 136.0 (ortho), 135.5 (ipso), 133.6 (ipso), 130.1 (para), 129.6 (para), 129.3 (meta), 129.0 ppm (meta).

²⁹Si NMR (99.4 MHz, CD₂Cl₂, 298 K): δ=−90.7 ppm (q, ¹J_{HSI}=204 Hz).

Synthesis of H₃Si—(Ph₂Ge)₄—SiH₃ (A8)

An NMR tube was filled with [nBu₄N]Cl (10 mg, 0.03 mmol, 0.2 eq.), Ph₂GeCl₂ (50 mg, 0.17 mmol, 1 eq.), 0.5 ml of CD₂Cl₂ and Si₂Cl₆ (90 mg, 0.34 mmol, 2 eq.). ¹³C and ²⁹Si NMR spectroscopy of the clear, colorless solution confirmed the presence of Cl₃Si-Ph₂Ge-Ph₂Ge—SiCl₃, Cl₃Si-Ph₂Ge—SiCl₃ and SiCl₄. The NMR tube was opened and all volatile constituents were removed under ambient pressure. The residue was dissolved in a new NMR tube in 0.5 ml of Et₂O and LiAlH₄ (7 mg, 0.17 mmol, 1 eq.) was added. A colorless solution with a gray sediment and a fine, colorless solid was then present. ¹³C and ²⁹Si NMR spectroscopy of the reaction solution gave the signals of several unknown species which could not be characterized more precisely. After opening the NMR tube and removing the volatile constituents under ambient pressure, a crystal was obtained which was identified by means of X-ray diffractometry as the tetragerman H₃Si—(Ph₂Ge)₄—SiH₃.

Synthesis Examples for the Compounds of the Formula (Ib)

Synthesis of C₁₀H₃₀Cl₄Ge₅Si₉ (C1)

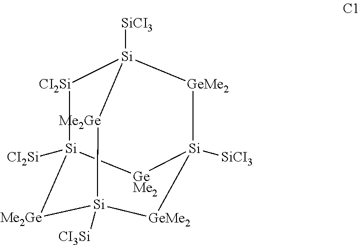

[nBu₄N]Cl (161 mg, 0.58 mmol, 0.2 eq.), Me₂GeCl₂ (500 mg, 2.88 mmol, 1 eq.), 10 ml of CH₂Cl₂ and Si₂Cl₆ (3092 mg, 11.5 mmol, 4 eq.) were stirred at room temperature for 3 hours and then all volatile constituents were removed under reduced pressure. The crude product was washed twice with 5 ml of n-hexane each time and the residue was dissolved in CH₂Cl₂. A colourless solid crystallized out over time. Washing with CH₂Cl₂ yielded C1 (4%, 32 mg, 0.025 mmol) as a colorless crystalline solid. The product was characterized by means of X-ray diffractometry (orthorhombic, Cmc2₁) and NMR spectroscopy.

¹H NMR (500.2 MHz, CD₂Cl₂, 298 K): δ=1.00, 0.94, 0.93 ppm.

¹³C{¹H} NMR (125.8 MHz, CD₂Cl₂, 298 K): δ=2.57, 2.23, 1.97 ppm.

²⁹Si NMR (99.4 MHz, CD₂Cl₂, 298 K): δ=16.2, 12.1, −80.7, −83.3 ppm.

Synthesis of C₈H₂₄Cl₁₆Ge₄Si₁₀ (C2)

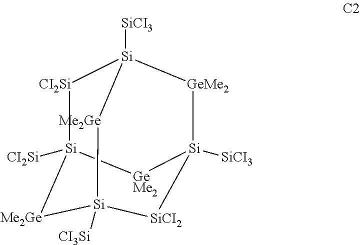

[nBu₄N]Cl (161 mg, 0.58 mmol, 0.2 eq.), Me₂GeCl₂ (500 mg, 2.88 mmol, 1 eq.), 10 ml of CH₂Cl₂ and Si₂Cl₆ (3092 mg, 11.5 mmol, 4 eq.) were filled into a bulkhead bottle. After a few days, colorless crystals had formed which could be isolated by means of filtration. Washing with CH₂Cl₂ yielded C2 (18%, 163 mg, 0.13 mmol) as a colorless crystalline solid. The product was characterized by means of X-ray diffractometry (trigonal, R-3) and NMR spectroscopy.

¹H NMR (500.2 MHz, CD₂Cl₂, 298 K): δ=1.03 ppm.

¹³C{¹H} NMR (125.8 MHz, CD₂Cl₂, 298 K): δ=1.59 ppm.

²⁹Si NMR (99.4 MHZ, CD₂Cl₂, 298 K): δ=11.9, −80.8 ppm.

Synthesis of C₂₂H₆₆Cl₂Ge₅Si₉ (C3)

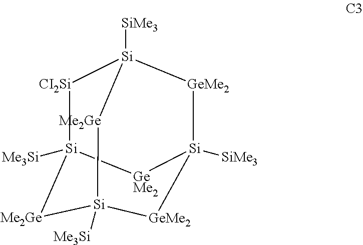

C1 (12 mg, 0.009 mmol, 1 eq.) and 0.5 ml of Et₂O were filled into an NMR tube and an Et₂O solution of MeMgBr (3 M, 0.1 ml, 0.30 mmol, 30 eq.) was added with ice cooling. The NMR tube was melted in under vacuum. After about two weeks at room temperature, a complete conversion could be observed by means of NMR spectroscopy. The NMR tube was then opened, the contents were transferred together with 3 ml of Et₂O into a Schlenk flask and then 0.05 ml of MeOH was added with ice cooling. After stirring for 10 minutes, all volatile constituents were removed, and the residue was extracted with a total of 7 ml of n-hexane. Again, all volatile constituents were removed from the extract, whereupon C3 (82%, 8 mg, 0.008 mmol) was obtained as a colorless crystalline solid. The product was characterized by means of X-ray diffractometry (orthorhombic, Cmcm) and NMR spectroscopy.

¹H NMR (500.2 MHz, CD₂Cl₂, 298 K): δ=0.66, 0.61, 0.59, 0.35, 0.27 ppm.

¹³C{¹H} NMR (125.8 MHz, CD₂Cl₂, 298 K): δ=4.06, 3.81, 3.60, 3.27, 2.92 ppm.

²⁹Si NMR (99.4 MHz, CD₂Cl₂, 298 K): δ=2.6, 3.5, 91.5, 97.2 ppm.

Synthesis of C₂₀H₆₀Cl₄Ge₄Si₁₀ (C4)

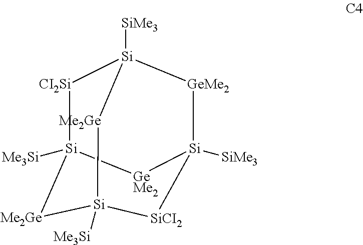

C2 (20 mg, 0.015 mmol, 1 eq.) and 0.5 ml of Et₂O were filled into an NMR tube and an Et₂O solution of MeMgBr (3 M, 0.2 ml, 0.60 mmol, 40 eq.) was added with ice cooling. The NMR tube was melted in under vacuum. After heating for 14 h at 60° C., a complete conversion could be observed by means of NMR spectroscopy. The further purification was then carried out analogously to C3.

Finally, C4 (89%, 16 mg, 0.016 mmol) was obtained as a colorless crystalline solid. The product was characterized by means of X-ray diffractometry (orthorhombic, Pbca) and NMR spectroscopy.

¹H NMR (500.2 MHz, CD₂Cl₂, 298 K): δ=0.70, 0.37 ppm.

¹³C{¹H} NMR (125.8 MHz, CD₂Cl₂, 298 K): δ=3.7, 2.5 ppm.

²⁹Si NMR (99.4 MHz, CD₂Cl₂, 298 K): δ=−1.8, −91.6 ppm.

Preparation of Si- and Ge-Containing Solids

Si- and Ge-Containing Solids can be prepared starting from the compounds according to the invention, for example according to the following reaction scheme.

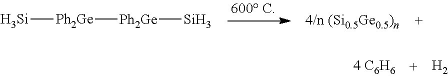

Deposition of SiGe at 600° C.

H₃Si-Ph₂Ge-Ph₂Ge—SiH₃ (13 mg, 0.025 mmol) was weighed into a crucible and a thermogravimetric analysis (TGA) was carried out. For this purpose, the mixture was heated to 600° C. under an argon atmosphere at a rate of 10 K/min, this temperature was maintained for 5 minutes and the sample was then cooled again to room temperature at the same rate. The residue obtained, a brownish powder, was examined by means of EDX. For this purpose, some of the sample was applied to a support and coated with gold for better measurement accuracy. In addition to silicon and germanium, the subsequent measurement showed only gold, as well as small amounts of carbon, oxygen and aluminum. The evaluation of the data of two analyzed regions showed a silicon-germanium ratio of 1.0:1.0 or 1.0:1.1.

The features of the invention disclosed in the above description and in the claims can be essential both individually and in any combination for the realization of the invention in its various embodiments.

1. A compound of the formula (Ia) or (Ib) 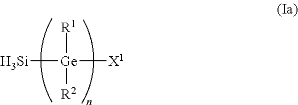
in which formula (Ia)
n is an integer from 1 to 10;
R¹ and R² are independently of each other selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl and C₇ to C₂₀ alkylaryl; and
X¹ is selected from the group consisting of H, SiH₃, halogen and Si(Y¹)₃ with Y¹=halogen; 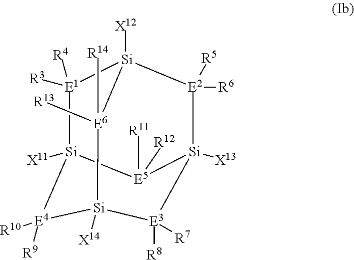
in which formula (Ib)
E¹ to E⁶ are independently of each other Si or Ge;
X¹¹ to X¹⁴ are independently of each other selected from the group consisting of H, SiH₃, halogen and Si(Y²)₃;
Y² is independently selected from C₁ to C₂₀ alkyl and halogen;
R³ to R¹⁴ are independently of each other selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl, C₇ to C₂₀ alkylaryl and Z; and
Z is independently selected from the group consisting of H, halogen and C₁ to C₂₀ alkyl.

2. A compound according to claim 1, wherein n is an integer from 1 to 4.

3. A compound according to claim 1, wherein R¹ and R² are independently of each other selected from the group consisting of C₁ to C₂₀ alkyl and C₆ to C₂₀ aryl.

4. A compound according to claim 1, wherein R¹ and R² are independently of each other phenyl or methyl.

5. A compound according to claim 1, wherein R¹ and R² are the same.

6. A compound according to claim 1, wherein X1 is selected from the group consisting of H, SiH₃, Cl and SiCl₃.

7. A compound according to claim 1, wherein at least three of E¹ to E⁶ are Ge and the remaining of E¹ to E⁶ are Si.

8. A compound according to claim 1, wherein R³ to R¹⁴ are independently of each other selected from the group consisting of C₁ to C₂₀ alkyl and halogen.

9. A compound according to claim 1, wherein R³ to R¹⁴ are independently of each other selected from the group consisting of methyl and Cl.

10. A compound according to claim 1, wherein X¹¹ to X¹⁴ are independently selected from the group consisting of H, SiH₃, Si(C₁ to C₄ alkyl)₃, Cl and SiCl₃.

11. A compound according to claim 1, wherein X¹¹ to X¹⁴ are independently selected from the group consisting of SiCl₃ and Si(CH₃)₃.

12. Process for preparing a compound of the formula (Ia) according to claim 1 comprising
reacting a compound of the formula (IIa) 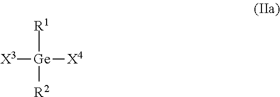
with a compound of the formula (IIIa) 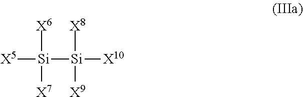
wherein
X³ to X¹⁰ are independently of each other halogen; and
R¹ and R² are as defined in one of the preceding claims; and
hydrogenating the product obtained by reacting the compound of the formula (IIa) with the compound of the formula (IIIa).

13. The process according to claim 12, wherein the reaction of the compound of the formula (IIa) with the compound of the formula (IIIa) is carried out in the presence of a catalyst.

14. Process for preparing a compound of the formula (Ib) according to claim 1 comprising
reacting a compound of the formula (IIb) 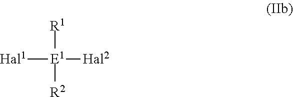
with a compound of the formula (IIIb) 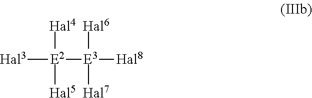
wherein
Hal¹ to Hal⁸ are independently of each other halogen; and
R³ and R⁴ are as defined in one of the preceding claims; and
crystallizing the product of the reaction of the compounds (IIb) and (IIIb).

15. The process according to claim 14, wherein the reaction of the compound of the formula (IIb) with the compound of the formula (IIIb) is carried out in the presence of a catalyst.

16. The process according to claim 14, further comprising reacting the product obtained after the crystallization with a Grignard reagent.

17. Process for preparation of a Si- and Ge-containing solid, comprising heating the compound of the formula (Ia) or the compound of the formula (Ib) according to claim 1.

18. The process according to claim 17, wherein the preparation comprises heating the compound to a temperature of 300° C. or more.
